(19) United States
(12) Patent Application Publication
(10) Pub. No.: US 2022/0136897 A1
(43) Pub. Date: May 5, 2022

(54) LOW CURRENT DETECTION

(71) Applicant: ams Sensors Germany GmbH, Jena (DE)

(72) Inventors: Dalibor Stojkovic, Erfurt (DE); Predrag Micakovic, Erfurt (DE)

(21) Appl. No.: 17/435,070

(22) PCT Filed: Mar. 9, 2020
(86) PCT No.: PCT/EP2020/056160

§ 371 Date: Aug. 31, 2021

Related U.S. Application Data
(60) Provisional application No. 62/815,186, filed on Mar. 7, 2019.

(51) Int. Cl. G01J 1/46; H03M 3/00

(52) U.S. Cl. CPC G01J 1/46; G01J 2001/446; H03M 3/458

(57) ABSTRACT

A sensor arrangement for light sensing for light-to-frequency conversion. The sensor arrangement includes a photodiode, an integrator operable to perform an integration phase during an integration time by converting a photocurrent generated by the photodiode into an input voltage, a voltage analog-to-digital converter (ADC) operable to perform a modulation phase by converting the input voltage (V_{IN}) into a digital output signal (ADC_RESULT) which is indicative of the photocurrent generated by the photodiode, a first switch electrically coupled to the photodiode and the integrator input, and a second switch electrically coupled to the input voltage node and a second reference voltage.

### BACKGROUND

Modern consumer electronics (e.g., smartphones) make increasing use of many different sensors which are often included in the same device. In one particular application, ambient light sensors are used for display management where these sensors measure the ambient light brightness. Depending on the brightness of the ambient light, the display illumination can be adjusted, and power can be saved. If, for example, the ambient light is bright, a higher backlight illumination for display panel may be needed. If, however, the ambient light is less, a lower backlight illumination for display panel may be sufficient. By dynamically adjusting the display panel brightness, ambient light sensors help the display panel to optimize the operation power.

Ambient light sensors may contain photodiodes that convert incoming light to analog signals. The analog signals may be digitized using analog-to-digital converter circuitry. The digitized signals can be used in adjusting display brightness and taking other actions in a device. It can be challenging to accurately convert light into digital measurements. If care is not taken, it may be difficult or impossible for analog-to-digital converter circuitry to accurately convert photodiode signals into digital light measurements.

### SUMMARY

This specification describes technologies relating to low current detection using integration and delta-sigma modulation simultaneously in each ambient light sensor (ALS) measurement to measure low light accurately.

In general, one innovative aspect of the subject matter described in this specification can be embodied in a sensor arrangement to perform an integration-modulation technique, the sensor arrangement including a photodiode, an integrator operable to perform an integration phase during an integration time (T_{INT}) by converting a photocurrent (I_{IN}) generated by the photodiode into an input voltage (V_{IN}), the integrator including an integrator input, an amplifier comprising an input electrically coupled to the integrator input, an integrating capacitor electrically coupled to the input and an output of the amplifier, and an integrator output electrically coupled to an output of the amplifier, the integrating capacitor, and an input voltage node, the integrator output providing an output signal to the input voltage node, a voltage analog-to-digital converter (ADC) operable to perform a modulation phase by converting the input voltage (V_{IN}) into a digital output signal (ADC_RESULT) which is indicative of the photocurrent generated by the photodiode, the ADC including an input electrically coupled to the input voltage node, a first power terminal electrically coupled to a first reference voltage (VREFP), and a second power terminal electrically coupled to the second reference voltage (VREFN), a first switch electrically coupled to the photodiode and the integrator input, and a second switch electrically coupled to the input voltage node and a second reference voltage.

Some implementations include one or more of the following features.

In some implementations, the integration-modulation technique comprises two or more integration-modulation cycles. In some implementations, each integration-modulation cycle comprises a reset phase, an integration phase, and a modulation phase. In some implementations, the integration phase and the modulation phase are performed simultaneously after the reset phase.

In some implementations, during each integration-modulation cycle, a voltage level of the input voltage (V_{IN}) starts at the second reference voltage (VREFN) following the reset phase, and the voltage level of the input voltage (V_{IN}) ramps up proportional to the photocurrent (I_{IN}) generated by the photodiode during the integration time (T_{INT}) for the integration phase.

In some implementations, the ADC further comprises a counter, wherein during the reset phase the counter does not change a current counter state. In some implementations, during the reset phase, the first switch is in an open state, the second switch is in a closed state, and the input voltage (V_{IN}) is set to the second reference voltage (VREFN).

In some implementations, each integration-modulation cycle is repeated based on an adjustment for a full scale current condition. In some implementations, the full scale current condition is determined by the input voltage (V_{IN}) ramping up during the integration time (TINT) for the integration phase to the value of the first reference voltage (VREFP).

In some implementations, the first and second reset switch operate in response to a clock signal. In some implementations, the ADC comprises a delta-sigma modulator operable to perform in a voltage mode.

In some implementations, each modulation phase comprises a plurality of modulation cycles. In some implementations, a number of the plurality of modulation cycles is programmable.

In some implementations, the digital output signal is proportional to the photocurrent (I_{IN}) and the input voltage (V_{IN}).

In general, one innovative aspect of the subject matter described in this specification can be embodied in a method including generating, from a light source by a photodiode, a photocurrent (I_{IN}), converting, by an integrator performed during an integration time (T_{INT}) for an integration phase of an integration-modulation cycle, the photocurrent (I_{IN}) into an input voltage (V_{IN}) at an input voltage node, the integrator including an integrator input, an amplifier comprising an input electrically coupled to the integrator input, an integrating capacitor electrically coupled to the input and an output of the amplifier, and an integrator output electrically coupled to an output of the amplifier, the integrating capacitor, and an input voltage node, the integrator output providing an output signal to the input voltage node, converting, by a voltage analog-to-digital converter (ADC) during a modulation phase of the integration-modulation cycle, the input voltage (V_{IN}) into a digital output signal (ADC_RESULT), the ADC including an input electrically coupled to the input voltage node, a first power input electrically coupled to a first reference voltage (VREFP), a second power input electrically coupled to the second reference voltage (VREFN), and resetting, by a reset switch, the input voltage (V_{IN}) to the second reference voltage (VREFN) during a reset phase.

Some implementations include one or more of the following features.

In some implementations, the integration phase and modulation phase are performed simultaneously during the integration time (T_{INT}). In some implementations, the integration-modulation cycle comprises a reset phase, an integration phase, and a modulation phase. In some implementations, the integration phase and the modulation phase are performed simultaneously subsequent the reset phase. In some implementations, an integration-modulation technique comprises two or more integration-modulation cycles.

In some implementations, during each integration-modulation cycle, a voltage level of the input voltage (V_{IN}) starts at the second reference voltage (VREFN) following the reset phase, and the voltage level of the input voltage (V_{IN}) ramps up proportional to the photocurrent (I_{IN}) generated by the photodiode during the integration time (T_{INT}).

In some implementations, during the reset phase, the first switch is in an open state, the second switch is in a closed state, and the input voltage (V_{IN}) is set to the second reference voltage (VREFN).

Some embodiments of the subject matter described in this specification can be implemented so as to realize one or more of the following advantages. By using the disclosed circuit arrangement and methodology with integration and modulation performed at the same time, better signal-to-noise ratio (SNR) performance for the case of low-current detection is achieved. Additionally, this integration-modulation technique is useful to provide full scale current (IFS) by adjustment of an integrator reset period which can provide more degrees of freedom for adjusting full-scale range IFS. The sensor arrangement described in this disclosure also can be integrated easily into existing architecture.

The sensor arrangement can be used for both light sensing and temperature sensing applications using the same signal path for sensor signal acquisition. By using the same signal path for both sensors, the silicon area of the sensor arrangement can be kept small. Thus, the sensor arrangement can be produced, in some cases, at lower cost.

The details of one or more embodiments of the subject matter described in this specification are set forth in the accompanying drawings and the description below. Other aspects, features, and advantages will become apparent from the description, the drawings, and the claims.

### BRIEF DESCRIPTION OF THE DRAWINGS

FIG. 1 is an example implementation of a sensor arrangement for light sensing.

FIG. 2 is an example diagram for the sensor arrangement for light sensing of FIG. 1 utilizing a current modulation phase.

FIG. 3 is an example implementation of a sensor arrangement for light sensing.

FIG. 4 is an example diagram for the sensor arrangement for light sensing of FIG. 3 utilizing separate integration and voltage ADC conversion phases.

FIG. 5 is an example diagram for the sensor arrangement for light sensing of FIG. 3 utilizing simultaneous integration and voltage ADC conversion phases.

### DETAILED DESCRIPTION

This disclosure describes a light sensor architecture for optimizing low current detection using integration and delta-sigma modulation simultaneously. In particular, this disclosure relates generally to sensor systems and more, particularly, light-to-digital (LTD) converters. For example, light sensors for color detection, color spectral sensors, and the like. The light sensor architecture has applications such as an ambient light sensor or color sensor where a light sensor is used to measure the level of light. This document describes an arrangement that optimizes a method for sensitivity limit (e.g., signal-to-noise ratio (SNR)) of the conventional LTD using a 1st order delta sigma modulator.

This disclosure is based on integration of a resettable integrator and a voltage delta sigma analog to digital converter (ADC). In some implementations, integration of the photodiode current and modulation can work at the same time. During each cycle, a modulator works as a voltage ADC with a voltage ramp which starts from a first reference voltage (V_{REF}) to a voltage proportional to the photodiode current. In some implementations, after a programmable number of modulation cycles analog to digital conversion is paused and the integrator is shortly in a reset state at the first reference voltage (V_{REF}). Integration and reset phase can be repeated until a total number of cycles has been reached. In some implementations, each integration cycle takes a same amount of time which can be accomplished for the case when the ratio of modulation cycles per total number of cycles is an integer.

These features, as well as additional features, are described in more detail below.

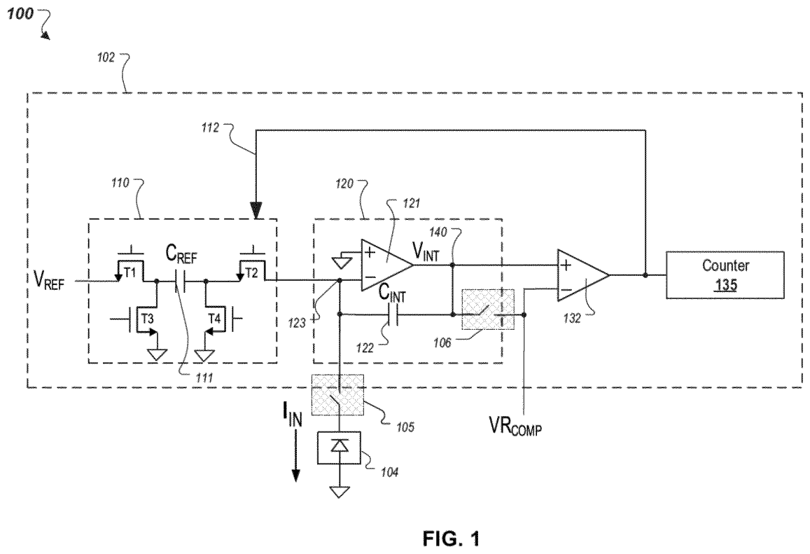

FIG. 1 is an exemplary implementation of an optical sensor arrangement 100. The sensor arrangement 100 includes a first order delta sigma modulator circuit 102 and a photodiode 104. The first order delta sigma modulator circuit 102 includes a reference charge circuit 110, an integrator 120, a comparator 132, and a digital counter 135. The first order delta sigma modulator circuit 102 operates as a light-to-frequency converter which may be implemented as an integrated circuit.

In some implementations, the photodiode 104 is connected to the integrated circuit as an external component. Alternatively, the photodiode 104 can be a part of the integrated circuit in some embodiments. The light-to-frequency converter and photodiode can be considered an optical sensor arrangement. In some embodiments, the optical sensor arrangement is used as an ambient light sensor.

The reference charge circuit 110 provides the reference charge (V_{REF}) to the first order delta sigma modulator circuit 102. The reference charge circuit 110 includes a plurality of switches (T1, T2, T3, and T4) and a reference capacitor (C_{REF}) 111. In some implementations, the switches are MOSFETS. Each switch includes a first terminal, a second terminal, and a third terminal, and the third terminal of the first switch receives a control signal that places the first switch in either a closed state in which a conduction path is established between the first and second terminals, or an open state in which the conduction path is eliminated between the first and second terminals. Switches T1 and T2 are connected to a first clock signal, and switches T3 and T4 are connected to a second clock signal, where each clock signal are non-overlapping clock signals. In some implementations, each switch operates at a magnitude limit for the switching voltage of substantially half of the DC input voltage (V_{REF}).

The reference capacitor 111 is coupled via reference switch T2 to the input of the integrator 120. Thus, the reference capacitor 111 is coupled to the amplifier 121 input by the reference switch T2. The reference capacitor 111 provides a variable capacitance value C_{REF}. The capacitance value C_{REF} of the reference capacitor 111 is set by a capacitor control signal.

The photodiode 104 is coupled to a photodiode input of the first order delta sigma modulator circuit 102 through a reset switch 105. The first order delta sigma modulator circuit 102 includes an integrator 120 that, in turn, includes an amplifier 121, an integrator input, and an integrator output. The amplifier 121 includes an amplifier input connected to the reset switch 105 which is connected to photodiode input of the first order delta sigma modulator circuit 102. In some implementations, the amplifier input is implemented as an inverting input. Alternatively, the amplifier input can be implemented as a non-inverting input. The amplifier 121 includes a further amplifier input that is designed as a non-inverting input, for example. The photodiode 104 connects the photodiode input of the first order delta sigma modulator circuit 102 to a reference potential terminal. An integrating capacitor 122 of the integrator 120 connects the amplifier input to an amplifier output of the amplifier 121. The resulting amplifier output includes the integrated voltage (V_{INT}) converted from the input photodiode current (I_{IN}). The amplifier output of the amplifier 121 is connected to the integrated voltage (V_{INT}) node 140. The integrated voltage (V_{INT}) node 140 further connects to the integrating capacitor 122 and a reset switch 106.

The first order delta sigma modulator circuit 102 includes a comparator 132 having a non-inverting input that is connected to the amplifier 121 output via the integrated voltage (V_{INT}) node 140. The comparator 132 input is implemented as a non-inverting input, for example. A further input of the comparator 132 is designed as an inverting input, for example. A reference voltage source VR_{COMP} connects the further input to the reference potential terminal and the reset switch 106. An output of the comparator 132 is connected to a digital counter 135 and a feedback loop 112. The feedback loop is connected to the reference charge circuit 110. The counter 135 includes a control input and control logic as well as one or more clock generators (not shown). During operation, in particular, during a reset phase, the reset switch 106 is switched on to a closed state by a reset switch signal S_{RESET}, and the integrated voltage (V_{INT}) will convert to the reference voltage source VR_{COMP} at the integrated voltage (V_{INT}) node 140. Similarly, during the reset phase, the reset switch 105 is switched to an open state by a reset switch signal S_{RESET}.

Sensor signal acquisition is initialized by applying an input control signal ADC_ON and an integration time signal S_{TINT} to a control input of a digital control circuit. A modulation clock signal T_{CLKMOD} (sometimes referred to herein as “T_{CLK}”) can be provided by a clock generator and/or be generated by a digital control circuit. Preferably, the sensor arrangement 100 is cleared before signal acquisition proceeds. As the input control signal ADC_ON is provided to the control input operation of the first order delta sigma modulator circuit 102 is triggered. The bias source Vb provides the amplifier reference voltage V_{REF} to the reference capacitor 111. The reference capacitor 111 generates a charge package QREF. The charge package QREF has a value according to

Q_{ref}=V_{ref,in}·C_{ref}

where C_{ref} is a capacitance value of the reference capacitor 111 and V_{ref,in} is a voltage value of the amplifier reference voltage V_{REF}. The digital control circuit provides a reference signal S2 to the reference switch T2. After closing the reference switch T2, the charge package QREF is applied to the input of the integrator 120 at the integrator input node 123.

Depending on an input control signal ADC_ON, and after the sensor arrangement 100 has been set or cleared to an initial condition, the photodiode 104 starts signal acquisition and generates a photocurrent IPD (I_{IN}). The value of the photocurrent depends on the intensity of the light incident on the photodiode 104. The photocurrent IPD flows through the photodiode 104 and the input of the first order delta sigma modulator circuit 102 to the integrator 120 through the reset switch 105. Each of the photodiode 104, the inverting input of the amplifier 121, and the integrating capacitor 122 are connected to the integration input node 123. In addition, the reference capacitor 111 is coupled to the integration input node 123 via the reference switch T2. The sensor current IPD flows from the integration input node 123 to the reference potential terminal with a positive value. The bias source Vb provides an amplifier reference voltage Vb to the non-inverting input of the amplifier 121. The amplifier 121 generates an output voltage VOUT at the integration voltage (V_{INT}) node 140.

In the case the reference switch T2 is open, the photocurrent IPD is integrated on the integrating capacitor 122. The output voltage VOUT rises with time t as:

V_{OUT}=I_{PD}·t·C_{INT}

where I_{PD} is a value of the photocurrent and C_{INT} denotes a capacitance value of the integrating capacitor 122. The output voltage VOUT of the amplifier 121 is applied as integration voltage (V_{INT}) to the non-inverting input of the comparator 132.

During signal acquisition, a signal processing unit counts the pulses of the comparator output signal LOUT. Basically, the counting is performed by the counter 135. Together, the reference charge circuit 110, the integrator 120, the comparator 132, and the counter 135 can be considered a first order modulator that generates an asynchronous count. The asynchronous count is directly proportional to the photocurrent (I_{IN}) integrated on the integrating capacitor 122 (within an error margin). According to some implementations, the asynchronous count may be prone to error, which can be accounted for by a signal processing engine. The counter 135 provides the synchronous count. This count comprises an integer number of individual counts (ADC Result). In some implementations, the comparator 132 can be implemented, for example, as a latched comparator.

The basic operation principle of an ALS circuit, such as the sensor arrangement 100 as shown in FIG. 1, is that the charge balancing analog-to-digital converter (ADC), collects the photon current from photodiode and converts it to an ALS count (ADC-COUNT). ALS count is based on a charge conservation equation:

ADC_COUNT=(Tᵢₙₜ*I_{pd})/(C_{ref}*V_{ref})

where Tᵢₙₜ is a total conversion time, I_{pd} is a value of the photocurrent (I_{IN}), Cref is the capacitance value of the reference capacitor 111, Vref is the reference voltage (V_{REF}). During a completely dark light condition, ideally, the photodiode will not generate any current, and the number of ADC counts is zero. Total ALS measurement time for every ALS integration cycle can be calculated by the equation:

ALS Measurement Time=AZ_Time+Init_Time+ALS_Integration_Time

where Init_Time is an initialization time and is a fixed time (e.g., 100 μs) irrespective of the gain, and AZ DAC and ALS_Integration_Time is a fixed time (e.g., 100 ms). AZ_Time is the auto zero time, and the auto zero time varies with the number of bits in the AZ DAC and the algorithm used to find the AZ code. For example, the higher the bits with the AZ DAC, the higher the AZ time and smaller amplifier 121 offset voltage. As the number of DAC bits increases, the overhead time in ALS measurement increases, can be the origin of the biggest overhead time in ALS measurements.

In some implementations, a user can program the integration time. For example, according to some implementations, a range of integration time (T_{INT}) can vary from 2.78 ms to 1400 ms. Alternatively, a different range of integration times can be used.

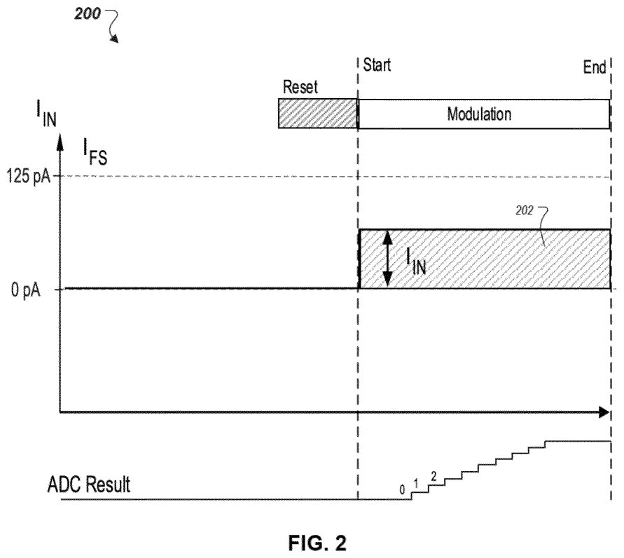

FIG. 2 is an example diagram 200 for the sensor arrangement 100 for light sensing of FIG. 1. In particular, diagram 200 illustrates the sensor arrangement 100 utilizing a current modulation phase.

A reset phase is used to define initial conditions for the integrator 120. During a reset phase, the photodiode current (I_{IN}) is at 0 pA. During a reset phase, the reset switch 105 is at an open state. In some implementations, an auto-zero operation is initially used, before the reset phase, to compensate effects produced by the amplifier 121 dc-offset voltage. An auto-zero operation can also get the offset voltage across photodiode 104 to a reasonable level (e.g., below ˜100 μV).

After a reset phase, the reset switch 105 is in a closed state and the first order delta sigma modulator circuit 102 starts continuous photodiode current integration on the integrating capacitor 122 (C_{INT}) capacitance over the integration time (T_{INT}). Modulator output (ADC Result) ramps linearly up proportionally to the input current after trip (VR_{COMP}) point has been reached and a negative step at the integrator 120 output is generated at integration voltage V_{INT} node 140. The photodiode current (I_{IN}) during modulation over the integration time (T_{INT}) produces a shaded area 202 under the photodiode current (I_{IN}) line. The ADC Result is proportional to the shaded area 202.

The integrator 120 amplitude (AA/NT) is calculated by the equation:

$$Δ {V}_{I N T} = \frac{{V}_{REF} * {C}_{REF}}{{C}_{INT}}$$

where C_{REF} is a capacitance value of the reference capacitor 111, V_{REF} is a voltage value of the amplifier reference voltage V_{REF}, and C_{INT} is a capacitance value of the integrating capacitor 122. Charge balancing feedback loop 112 continues until user programmed number of modulation cycles (ltf_itime+1) has been reached, where “itime+1” is the number of clock cycles from measurement start to end. For example, during a full scale condition, the comparator 132 delivers 1 at each clock cycle, which means that this is “itime+1”. During the integration time, COMP=1 “counts” which is the present result of the AD conversion. Full scale current (IFS) can be calculated as:

$$IFS = \frac{{V}_{REF} * {C}_{REF}}{{T}_{CLKMOD}}$$

where C_{REF} is a capacitance value of the reference capacitor 111, V_{REF} is a voltage value of the amplifier reference voltage V_{REF}, and T_{CLKMOD} is the modulation clock signal.

In the case of low current applications more signal counts can be produced by lowering full scale factor (IFS=V_{REF}*C_{REF}) assuming constant integration time T_{CLKMOD}. Limitation of this method is could be illustrated by the following example:

TABLE 1
Example Full Scale Current Condition

| | IFS | C_{REF} | C_{INT} | V_{REF} | ΔV_{INT} |
|---|---|---|---|---|---|
| T_{CLK—}MHz | [A] | [F] | [F] | [V] | [V] |
| 1 | 0.125n | 50f | 50f | 2.5m | 2.5m |

In the example as shown in Table 1, above, if full scale current is 125 pA, the amplitude at the reference voltage and output of integrator is 2.5 mV, which is below the integrator's noise level. This example for the sensor arrangement 100 portrays that further SNR improvement is not possible by increasing number of signal counts because noise counts will increase too.

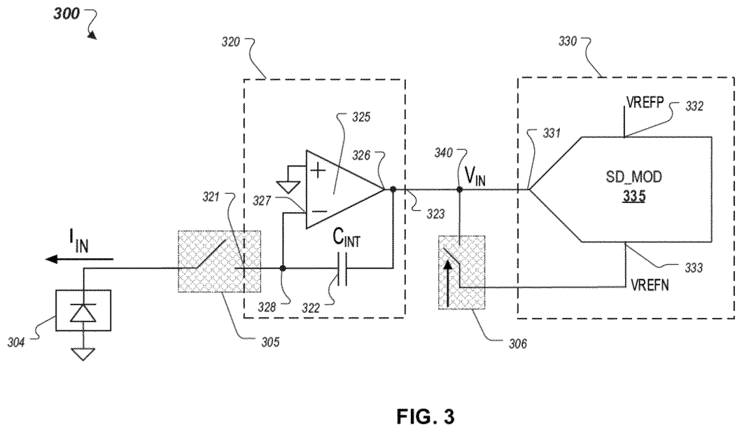

FIG. 3 is an exemplary implementation of a sensor arrangement 300. The sensor arrangement 300 includes a photodiode 304, an integrator 320, a first order sigma delta modulator (SD_MOD) circuit 330, and two reset switches 305, 306. The sensor arrangement 300 operates as a light-to-frequency converter which may be implemented as an integrated circuit.

In some implementations, the photodiode 304 is connected to the integrated circuit as an external component. Alternatively, the photodiode 304 can be a part of the integrated circuit in some embodiments. The sensor arrangement 300 with the photodiode 304 can be considered an optical sensor arrangement. In some embodiments, the optical sensor arrangement is used as an ambient light sensor.

The photodiode 304 is coupled to a photodiode input of the integrator 320 through a reset switch 305. The integrator 320 includes an amplifier 325, an integrator input 321, and an integrator output 323. The amplifier 325 includes an amplifier input 327 connected to the reset switch 305 which is connected to photodiode input 321 of the integrator 320. In some implementations, the amplifier input 327 is implemented as an inverting input, as shown. The photodiode 304 connects the photodiode input 321 of the integrator 320 to a ground reference potential terminal. An integrating capacitor 322 of the integrator 320 is electrically coupled to the amplifier input 327 and the amplifier output 326. The resulting amplifier output includes the integrated voltage (V_{INT}) (or sometimes referred to herein, and as shown in FIG. 3, as the input voltage V_{IN}). The integrated voltage (V_{INT}) is converted by the integrator 320 from the input photodiode current (I_{IN}). The amplifier output 326 is connected to the input voltage node 340. The input voltage node 340 further connects to the integrating capacitor 322 and a reset switch 306.

The first order sigma delta modulator circuit 330 includes a first order sigma delta modulator 335. The SD_MOD 335 can include similar circuit components for modulation as the shown in FIG. 1. For example, the SD_MOD 335 can include a comparator and a counter, as well as connect to control logic and a clock generator.

The SD_MOD 335 includes two reference voltage inputs 332, 333, connected to a positive reference voltage (VREFP) and a negative reference voltage (VREFN), respectively. The SD_MOD 335 further includes an output 331 that is connected to the integrated voltage (V_{INT}) node 340 which electrically connects the SD_MOD circuit 330 to the input voltage (V_{IN}). A reference potential terminal, such as the negative reference voltage (VREFN), connects the SD_MOD 335 to the reset switch 306. During operation, in particular, during a reset phase, the reset switch 306 is switched to a closed state by a reset switch signal S_{RESET}, and the integrated input voltage (V_{INT}) will convert to the negative reference voltage VREFN at the input voltage node 340. Thus, the reset switch 306, in operation, allows the integrator 320 to operate as a resettable integrator. Similarly, during the reset phase, the reset switch 305 is switched to an open state by a reset switch signal S_{RESET}, which prevents the photodiode current from flowing through the sensor arrangement 300 during a reset time period, which will be further discussed herein.

As discussed above with reference to FIG. 1, sensor signal acquisition is initialized by applying an input control signal ADC_ON and an integration time signal S_{TINT} to a control input of a digital control circuit. A modulation clock signal T_{CLKMOD} (sometimes referred to herein as “T_{CLK}”) can be provided by a clock generator and/or be generated by a digital control circuit. Preferably, the sensor arrangement 300 is cleared before signal acquisition proceeds. As the input control signal ADC_ON is provided to the control input operation of the sensor arrangement 300 is triggered. Depending on an input control signal ADC_ON, and after the sensor arrangement 300 has been set or cleared to an initial condition, the photodiode 304 starts signal acquisition and generates a photocurrent IPD (I_{IN}). The value of the photocurrent depends on the intensity of the light incident on the photodiode 304. The photocurrent IPD flows through the photodiode 304 and the input of the integrator 320 through the reset switch 305. Each of the photodiode 304, the inverting input 327 of the amplifier 325, and the integrating capacitor 322 are connected to the integration input node 328. The sensor current IPD (I_{IN}) flows from the integration input node 328 to the reference potential terminal with a positive value. The non-inverting input of the amplifier 325 is connected to ground. The amplifier 325 generates an output voltage VOUT at the amplifier output 326 which is electronically coupled to the integration input voltage node 140.

The photocurrent IPD is integrated on the integrating capacitor 122. The output voltage VOUT rises with time t as:

V_{OUT}=I_{PD}·t·C_{INT}

where I_{PD} is a value of the photocurrent and C_{INT} denotes a capacitance value of the integrating capacitor 322. The output voltage VOUT of the amplifier 325 is applied as integration voltage (V_{INT}) to a non-inverting input of a comparator of the SD_MOD 335.

During signal acquisition, a signal processing unit of the SD_MOD 335 counts the pulses of the comparator output signal LOUT. Basically, the counting is performed by a counter. The SD_MOD circuit 330 generates a synchronous count. The synchronous count is directly proportional to the photocurrent (I_{IN}) integrated on the integrating capacitor 322 (within an error margin). The count comprises an integer number of individual counts (ADC Result). In some implementations, the comparator can be implemented, for example, as a latched comparator.

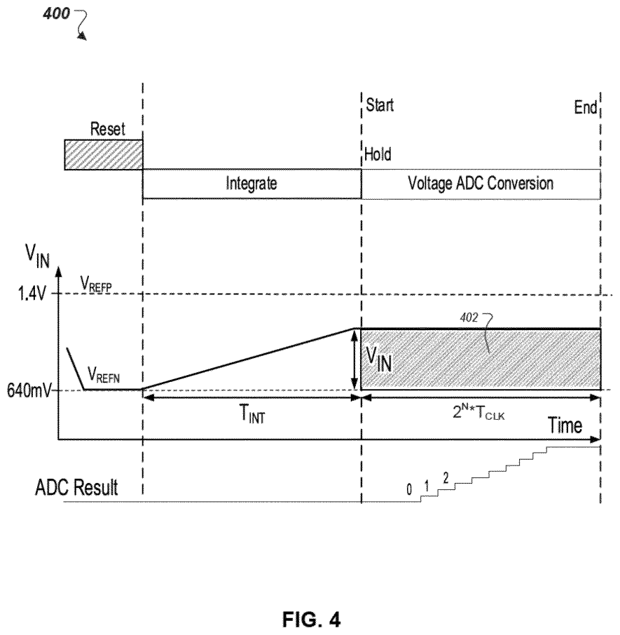

FIG. 4 is an example diagram 400 of the sensor arrangement 300 for light sensing of FIG. 3. In particular, diagram 400 illustrates the sensor arrangement 300 utilizing separate integration and voltage ADC conversion phases.

A reset phase is used to define initial conditions for the integrator 120. During a reset phase, the photodiode current (I_{IN}) is at 0 pA. During the reset phase, the reset switch 305 is in an open state, the reset switch 306 is in a closed state, and thus the voltage level of V_{IN} at the integration voltage node 140 is equivalent to the negative reference voltage VREFN. As shown in FIG. 4, an example VREFN is set at 640 mV. In some implementations, during operation, an auto-zero operation is initially used to compensate effects produced by the amplifier 325 dc-offset voltage. An auto-zero operation can also get the offset voltage across photodiode 304 to a reasonable level (e.g., below ˜100 μV).

After a reset phase, the reset switch 305 is in a closed state, the reset switch 306 is an open state, and the sensor arrangement 300 starts integration, which includes continuous photodiode current integration on the integrating capacitor 322 (C_{INT}) capacitance over the integration time (T_{INT}). During integration over the integration time (T_{INT}), the input voltage (V_{IN}) is increased linearly with the photocurrent (I_{IN}) and integration time.

After the integration over the integration time (T_{INT}) is complete, a hold phase is initialized. To initiate the hold phase, the current flow is disabled by opening the reset switch 305, and the input voltage (V_{IN}) is held at:

$${V}_{I N} = \frac{I i n * T i n t}{Cint}$$

where I_{IN} is current generated by the photodiode 304, T_{INT} is the integration time, and C_{INT} is a capacitance value of the integrating capacitor 322.

The hold phase initiates the voltage ADC conversion phase. During the voltage ADC conversion phase, the modulator output (ADC Result) from the SD_MOD 335 ramps linearly up proportionally to the input voltage (V_{IN}). The photodiode current (I_{IN}) during modulation over the voltage ADC conversion time period (2^{N}*T_{CLK}) produces a shaded area 402 under the input voltage (V_{IN}) line, as shown in FIG. 4. Where N is the number of bits of the ADC. The ADC Result is proportional to the shaded area 402.

Full scale current (IFS) condition, when V_{IN} reaches the positive reference voltage VREFP, can be calculated as:

$$IFS = \frac{C i n t * ( Vrefp - Vrefn )}{T i n t}$$

where C_{INT} is a capacitance value of the integrating capacitor 322, V_{REFP} is the positive reference voltage, V_{REFN} is the negative reference voltage, and T_{INT} is the integration time. For example, as shown in FIG. 4, VREFP is 1.4V, and VREFN is 640 mV. However, different ranges of the reference voltages may be used.

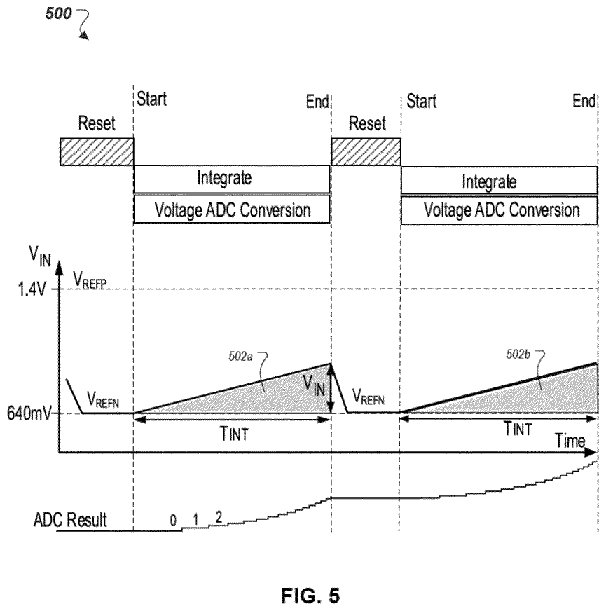

FIG. 5 is an example diagram 500 of the sensor arrangement 300 for light sensing of FIG. 3. In particular, diagram 500 illustrates the sensor arrangement 300 utilizing an integration-modulation technique for performing integration and voltage ADC conversion phases simultaneously, where integration of the photodiode current and modulation work at the same time.

In particular, during each cycle, the modulator (i.e., SD_MOD 335) works as a voltage ADC with a voltage ramp that starts from VREFN, following a reset phase, to the voltage proportional to photodiode current. After a programmable number of modulation cycles (ltf_ccount+1), ADC conversion is paused, and the integrator 320 is shortly in the reset state at the negative reference voltage VREFN. Integration and reset phase are repeated until the total number of cycles (ltf_itime+1) has been reached. In some implementations, each integration cycle takes a same amount of time which can be accomplished for the case when a ratio Ncycles is an integer:

$$Ncycles = \frac{( l t {f}_{itime} + 1 )}{( l t {f}_{c o u n t} + 1 )}$$

where (ltf_itime+1) is the total number of cycles, and (ltf_ccount+1) the programmed number of modulation cycles (ltf_ccount+1=T_{INT}).

Similarly to the reset phase described above in FIG. 4, a reset phase is used to define initial conditions for the integrator 120. During a reset phase, the photodiode current (I_{IN}) is at 0 pA. During the reset phase, the reset switch 305 is in an open state, the reset switch 306 is in a closed state, and thus the voltage level of V_{IN} at the integration voltage node 140 is equivalent to the negative reference voltage VREFN. As shown in FIG. 4, an example VREFN is set at 640 mV. In some implementations, during operation, an auto-zero operation is initially used to compensate effects produced by the amplifier 325 dc-offset voltage. An auto-zero operation can also get the offset voltage across photodiode 304 to a reasonable level (e.g., below ˜100 μV).

After a reset phase, the reset switch 305 is in a closed state, the reset switch 306 is an open state, and the sensor arrangement 300 starts integration and voltage ADC conversion, which includes continuous photodiode current integration on the integrating capacitor 322 (C_{INT}) capacitance over the integration time (T_{INT}). During integration over the integration time (T_{INT}), the input voltage (V_{INT}) is increased linearly with the photocurrent (I_{IN}) and integration time. Simultaneously, the voltage ADC conversion phase also occurs during the same integration time (T_{INT}), and the modulator output (ADC Result) from the SD_MOD 335 ramps linearly up proportionally to the input voltage (V_{IN}). The photodiode current (I_{IN}) during modulation over the integration time (T_{INT}), produces a shaded areas 502a, 502b, under the input voltage (V_{IN}) line, as shown in FIG. 5. The ADC Result is proportional to the shaded areas 502a, 502b. The reset phase and integration/modulation phases are repeated for adjustment of the full scale current condition.

Some example measurements for FIG. 5 is illustrated by the following example:

TABLE 2
Example Full Scale Current Condition

| Ncyc | ccount + 1 | itime + 1 | F_{CLK} [MHz] | IFS[pA] | C_{INT} [F] | C_{REF} [F] | C_{MOD} [F] | V_{REF} [V] | ΔV_{INT} [V] |
|---|---|---|---|---|---|---|---|---|---|
| 1 | 65536 | 65536 | 1 | 4.63 | 400 f | 50 f | 400 f | 760 m | 95 m |
| 2 | 32768 | 65536 | 1 | 9.26 | 400 f | 50 f | 400 f | 760 m | 95 m |
| 4 | 16384 | 65536 | 1 | 18.52 | 400 f | 50 f | 400 f | 760 m | 95 m |
| 5 | 8192 | 65536 | 1 | 37.04 | 400 f | 50 f | 400 f | 760 m | 95 m |
| 16 | 4096 | 65536 | 1 | 74.08 | 400 f | 50 f | 400 f | 760 m | 95 m |
| 32 | 2048 | 65536 | 1 | 148.16 | 400 f | 50 f | 400 f | 760 m | 95 m |

In the example as shown in Table 3, above, IFS is the full-scale current, C_{INT} is the integrator capacitance, C_{REF} is the reference capacitance, C_{MOD} is the delta sigma modulator capacitance, V_{REF} is the reference voltage, and ΔV_{INT} is the modulator amplitude.

Full scale current (IFS) condition, when V_{IN} reaches the positive reference voltage VREFP, can be calculated as:

$$IFS = \frac{C i n t * ( Vrefp - Vrefn )}{T i n t}$$

where C_{INT} is a capacitance value of the integrating capacitor 322, V_{REFP} is the positive reference voltage, V_{REFN} is the negative reference voltage, and T_{INT} is the integration time. For example, as shown in FIG. 4, V_{REFP} is 1.4V, and V_{REFN} is 640 mV. However, different ranges of the reference voltages may be used. An example full scale current condition is illustrated by the following example:

TABLE 3
Example Full Scale Current Condition

| | IFS[A]/ | C_{REF} | C_{INT} | V_{REF} | ΔV_{INT} |
|---|---|---|---|---|---|
| T_{CLK—}MHz | ccount | [F] | [F] | [V] | [V] |
| 1 | 4.63p @65k | 50f | 400f | 760m | 95m |

In the example as shown in Table 3, above, VREF is the differential reference voltage of VREFP−VREFN of FIG. 3. If full scale current is 4.63 pA at 65,000 cycles, the amplitude at the reference voltage and output of integrator is 95 mV, which is above the integrator's noise level. This example for the sensor arrangement 300 portrays that further SNR improvement is possible by increasing number of signal counts.

While this specification contains many specific implementation details, these should not be construed as limitations on the scope of any features or of what may be claimed, but rather as descriptions of features specific to particular embodiments. Certain features that are described in this specification in the context of separate embodiments also can be implemented in combination in a single embodiment. Conversely, various features that are described in the context of a single embodiment also can be implemented in multiple embodiments separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Similarly, while operations are depicted in the drawings in a particular order, this should not necessarily be understood as requiring that such operations be performed in the particular order shown or in sequential order, or that all illustrated operations be performed, to achieve desirable results. In certain circumstances, multitasking and parallel processing may be advantageous. Moreover, the separation of various system components in the embodiments described above should not be understood as requiring such separation in all embodiments, and it should be understood that the described program components and systems can generally be integrated together in a single software product or packaged into multiple software products.

Thus, particular embodiments of the subject matter have been described. In some cases, the actions recited in the claims can be performed in a different order and still achieve desirable results. In addition, the processes depicted in the accompanying figures do not necessarily require the particular order shown, or sequential order, to achieve desirable results. In certain implementations, multitasking and parallel processing may be advantageous. Accordingly, other implementations are within the scope of the following claims.

1. A sensor arrangement operable to perform an integration-modulation technique, the sensor arrangement comprising:
a photodiode;
an integrator operable to perform an integration phase during an integration time (T_{INT}) by converting a photocurrent (I_{IN}) generated by the photodiode into an input voltage (V_{IN}), the integrator comprising:
an integrator input;
an amplifier comprising an input electrically coupled to the integrator input;
an integrating capacitor electrically coupled to the input and an output of the amplifier; and
an integrator output electrically coupled to an output of the amplifier, the integrating capacitor, and an input voltage node, the integrator output providing an output signal to the input voltage node;
a voltage analog-to-digital converter (ADC) operable to perform a modulation phase by converting the input voltage (V_{IN}) into a digital output signal (ADC_RESULT) which is indicative of the photocurrent generated by the photodiode, the ADC comprising:
an input electrically coupled to the input voltage node;
a first power terminal electrically coupled to a first reference voltage (VREFP); and
a second power terminal electrically coupled to the second reference voltage (VREFN);
a first switch electrically coupled to the photodiode and the integrator input; and
a second switch electrically coupled to the input voltage node and a second reference voltage.

2. The sensor arrangement of claim 1, wherein the integration-modulation technique comprises two or more integration-modulation cycles.

3. The sensor arrangement of claim 2, wherein each integration-modulation cycle comprises a reset phase, an integration phase, and a modulation phase.

4. The sensor arrangement of claim 3, wherein the integration phase and the modulation phase are performed simultaneously after the reset phase.

5. The sensor arrangement of claim 3, wherein during each integration-modulation cycle, a voltage level of the input voltage (V_{IN}) starts at the second reference voltage (VREFN) following the reset phase, and the voltage level of the input voltage (V_{IN}) ramps up proportional to the photocurrent (I_{IN}) generated by the photodiode during the integration time (T_{INT}) for the integration phase.

6. The sensor arrangement of claim 3, wherein the ADC further comprises a counter, wherein during the reset phase the counter does not change a current counter state, the first switch is in an open state, the second switch is in a closed state, and the input voltage (V_{IN}) is set to the second reference voltage (VREFN).

7. The sensor arrangement of claim 1, wherein each integration-modulation cycle is repeated based on an adjustment for a full scale current condition.

8. The sensor arrangement of claim 7, wherein the full scale current condition is determined by the input voltage (V_{IN}) ramping up during the integration time (T_{INT}) for the integration phase.

9. The sensor arrangement of claim 1, wherein the first and second reset switch operate in response to a clock signal.

10. The sensor arrangement of claim 1, wherein the ADC comprises a delta-sigma modulator operable to perform in a voltage mode.

11. The sensor arrangement of claim 1, wherein each modulation phase comprises a plurality of modulation cycles.

12. The sensor arrangement of claim 11, wherein a number of the plurality of modulation cycles is programmable.

13. The sensor arrangement of claim 1, wherein the digital output signal is proportional to the photocurrent (I_{IN}) and the input voltage (V_{IN}).

14. A method for light-to-digital (LTD) conversion comprising:
generating, from a light source by a photodiode, a photocurrent (I_{IN});
converting, by an integrator performed during an integration time (T_{INT}) for an integration phase of an integration-modulation cycle, the photocurrent (I_{IN}) into an input voltage (V_{IN}) at an input voltage node, the integrator comprising:
an integrator input;
an amplifier comprising an input electrically coupled to the integrator input;
an integrating capacitor electrically coupled to the input and an output of the amplifier; and
an integrator output electrically coupled to an output of the amplifier, the integrating capacitor, and an input voltage node, the integrator output providing an output signal to the input voltage node;
converting, by a voltage analog-to-digital converter (ADC) during a modulation phase of the integration-modulation cycle, the input voltage (V_{IN}) into a digital output signal (ADC_RESULT), the ADC comprising:
an input electrically coupled to the input voltage node;
a first power input electrically coupled to a first reference voltage (VREFP);
a second power input electrically coupled to the second reference voltage (VREFN); and
resetting, by a reset switch, the input voltage (V_{IN}) to the second reference voltage (VREFN) during a reset phase.

15. The method of claim 14, wherein the integration phase and modulation phase are performed simultaneously during the integration time (T_{INT}).

16. The method of claim 14, wherein the integration-modulation cycle comprises a reset phase, an integration phase, and a modulation phase.

17. The method of claim 16, wherein the integration phase and the modulation phase are performed simultaneously subsequent the reset phase.

18. The method of claim 17, wherein an integration-modulation technique comprises two or more integration-modulation cycles.

19. The method of claim 14, wherein during each integration-modulation cycle, a voltage level of the input voltage (V_{IN}) starts at the second reference voltage (VREFN) following the reset phase, and the voltage level of the input voltage (V_{IN}) ramps up proportional to the photocurrent (I_{IN}) generated by the photodiode during the integration time (T_{INT}).

20. The method of claim 14, wherein during the reset phase, the first switch is in an open state, the second switch is in a closed state, and the input voltage (V_{IN}) is set to the second reference voltage (VREFN).
